(19) United States
(12) Patent Application Publication
(10) Pub. No.: US 2010/0259423 A1
(43) Pub. Date: Oct. 14, 2010

(54) SOUND DAMPENING INDIVIDUAL KEY FILTERS

(76) Inventor: MaryAnne K. Randall, Vancouver, WA (US)

Correspondence Address: CHERNOFF, VILHAUER, MCCLUNG & STENZEL, LLP, 601 SW Second Avenue, Suite 1600, PORTLAND, OR, 97204-3157, US

(21) Appl. No.: 12/748,909

(22) Filed: Mar. 29, 2010

Related U.S. Application Data
(60) Provisional application No. 61/168,361, filed on Apr. 10, 2009.

(51) Int. Cl. H03K 17/94

(52) U.S. Cl. 341/24

(57) ABSTRACT

An individual key filter capable of substantially reducing fingernail-to-key (or finger-to-key) impact noise and reducing the percussive sound generated by such fingernail-to-key impacts associated with the use of data entry devices such as, for example, computer keyboards or other data entry keypad devices.

### CROSS-REFERENCE TO RELATED APPLICATIONS

This application claims priority to U.S. Provisional Patent Application No. 61/168,361, filed Apr. 10, 2009, the entirety of which is hereby incorporated by reference.

### BACKGROUND OF THE INVENTION

This disclosure relates generally to individual key filters for data entry devices, and, more particularly, to individual key filters capable of substantially dampening the acoustic signatures produced by percussive patterns generated by data entry using keys on a keyboard or keypad. The substantially dampened and modified acoustic signatures reduces audible noise exacerbated by aggressive or rapid data entry or, notably, the commonly recognizable elevated noise due to fingernail impacts upon data entry keys.

Improved methods and apparatuses for acoustically modifying the sound created by finger and fingernail impacts on data entry keys are needed—for improvements (i.e. reductions) in sound levels in working environments, for improved counter-surveillance and privacy, for improved ergonomics using data entry devices, for improved data entry productivity, and for other benefits, some of which are further described herein.

The foregoing and other objectives, features, and advantages of the invention will be more readily understood upon consideration of the following detailed description of the invention taken in conjunction with the accompanying drawings.

### BRIEF DESCRIPTION OF THE DRAWINGS

For a more complete understanding of the present invention, the drawings herein illustrate examples of the invention. The drawings, however, do not limit the scope of the invention. Similar references in the drawings indicate similar elements.

### DETAILED DESCRIPTION OF THE DRAWINGS

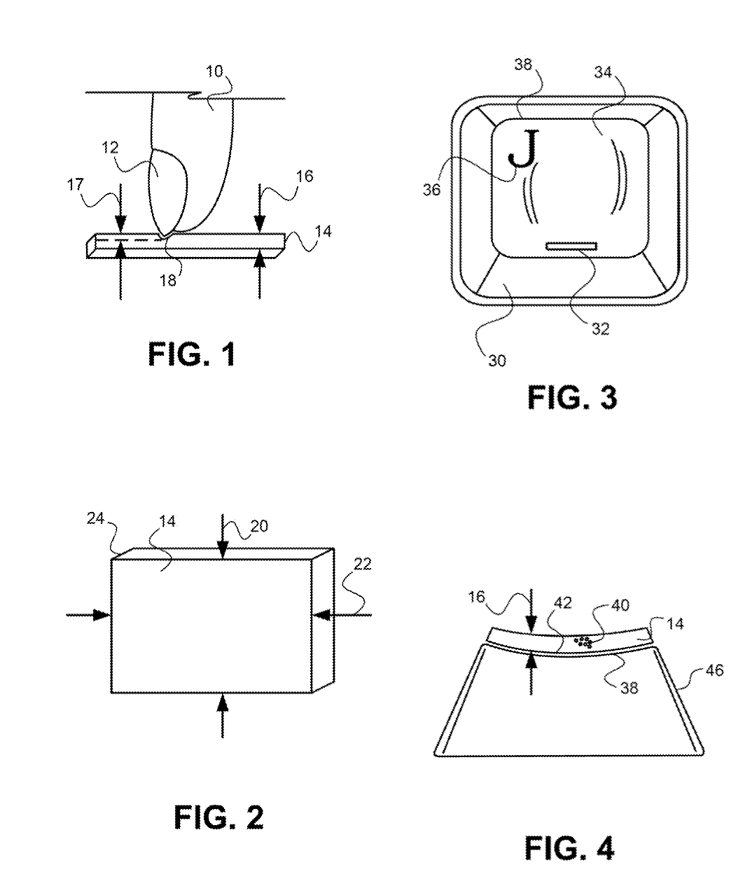

FIG. 1 illustrates a finger/fingernail striking an exemplary individual key filter, according to one embodiment.

FIG. 2 illustrates a top view of the exemplary individual key filter shown in FIG. 1.

FIG. 3 illustrates a top view of an exemplary individual key used on a typical keyboard or keypad.

FIG. 4 illustrates a side view of the exemplary individual key shown in FIG. 3 along with application of the exemplary individual key filter shown in FIGS. 1 and 2, according to one embodiment.

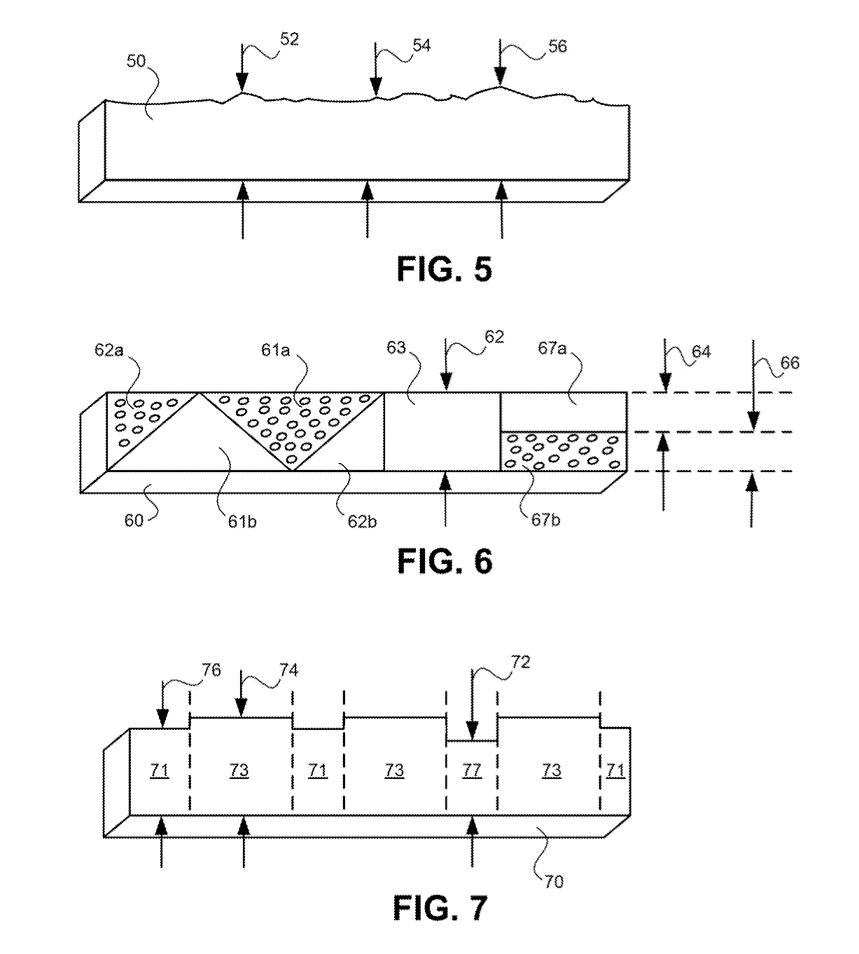

FIG. 5 illustrates a side view of an exemplary individual key filter having variable thickness, according to one embodiment.

FIG. 6 illustrates a side view of an exemplary individual key filter with variable material characteristics, according to various embodiments.

FIG. 7 illustrates a side view of an exemplary individual key filter with variable material characteristics and material thicknesses, according to various embodiments.

### DETAILED DESCRIPTION OF PREFERRED EMBODIMENTS

In the following detailed description, numerous specific details are set forth in order to provide a thorough understanding of various embodiments. However, those skilled in the art will understand that the present invention may be practiced without these specific details, that the present invention is not limited to the described embodiments, and that the present invention may be practiced in a variety of alternate embodiments. In other instances, well known methods, procedures, components, and systems have not been described in detail.

In a preferred embodiment resilient material 40 is placed within the top area 34, for example looking at the “J” key 36 in FIGS. 3 and 4. Data entry keys sometimes have cupped or indented or downwardly (into the keyboard) concave top surfaces within which an end of a user's finger or fingernail may be placed when resting on the key or depressing the key so as to enter the corresponding data triggered therefrom. Whether the top surface 34 is cupped (as in FIGS. 3 and 4) or flat or of some other contour, the individual key filter 14 placed over the top surface 34 preferably absorbs the impact and sound of a finger 10 and/or fingernail 12. For example, as shown in FIG. 1, such impact may be dampened or fully absorbed by deflection or localized compression of the individual key filter 14 at the point of impact 18. The impact may cause, for example, compression of the resilient material 40 from a normal thickness 16 down to a compressed thickness 17 where the fingernail 12 completes its downward (or inward toward the individual key filter 14 displacement (i.e. at the point of impact 18).

Sounds of finger-to-key and fingernail-to-key impacts give rise to security concerns with key-based data entry devices such as computer keyboards, data keypads, and the like. The sounds that may be recorded of a user of such unprotected devices may be used to discern the content of the information being entered by the user. That is, the keystrokes, i.e. magnitude of sound, spatial spectrum of the sound, frequency content of the sound, and other audible recordable characteristics may be used in identifying the characteristics of each key. The present inventor discovered that adhering a resilient sound absorbing material 40 to the top surface 38 of each individual key substantially reduces or practically eliminates the ability to discern the content of data being entered from audible recordings of the the user entering the data via the keys having the absorbent material fastened thereon.

The present inventor noted that researchers found that if you have an audio recording of somebody typing on an ordinary computer keyboard for approximately fifteen minutes, one can figure out everything that was typed. They found that different keys tend to make slightly different sounds, and without knowing in advance which keys make which sounds, one can use machine learning to figure out what was typed.

One group of researchers examined the problem of keyboard acoustic emanations and found that taking a 10-minute sound recording of a user typing English text using a keyboard could be used to recover up to 96% of typed characters, without requiring a labeled training recording for recognizing the typed characters. The recognizer was able to recognize random text such as passwords using a combination of standard machine learning and speech recognition techniques, including cepstrum features, Hidden Markov Models, linear classification, and feedback-based incremental learning.

Another group of researchers relied on store-bought microphones and a modified speech-recognition program to identify typed letters, with enough accuracy to correctly guess 10-digit passwords on one out of every 75 tries.

Each key on computer keyboards, telephones, ATM machines, and the like makes a unique sound as each key is depressed and released.

Most such devices have a rubber membrane underneath the keys that acts like a drum. Each key hits the membrane in a different location and produces a unique frequency or sound that neural networking software may be made to decipher.

The researchers found that by recording the same sound of a keystroke about 30 times and feeding it into a PC running standard neural networking software, they could decipher the keys with an 80% accuracy rate. They were also able to use the software on one keyboard so as to decipher keystrokes on any other keyboard of the same make and model. The researchers found that good sound quality is not required to recognize the acoustic signature or frequency of a key. They were able to extract the audio captured by a cellular phone and still successfully decipher the key strokes. They suggested the practical steps of closing the door in the room where you're working and using a rubber keyboard coffee guard to dampen the sound enough to make eavesdropping difficult. The researchers determined it is possible to use acoustical analysis algorithms to decipher key sounds based simply on gathering the data from just a couple of keys and extrapolating what other keys should sound like. They further determined that it was the membrane that was providing the unique signature and that simply by cutting a keyboard in two the neural networking software no longer worked.

The present inventor, however, determined that analysis of the sounds made by each particular key in a keyboard is not the same as the analysis of the percussive sounds generated by the finger or fingernail-to-key impacts. That is, prior research and observations regarding analysis of the characteristic sounds made by depressing keys on a keyboard does not address the sounds made by the finger-to-key or fingernail-to-key impact noises. Analysis of those sounds, even when the sounds made by depression of the keys themselves is fully eliminated, may be used to determine content of the information being communicated using the keyboard. The present inventor discovered that a fully dampened keyboard so as to minimize the sounds made by depression of the keys themselves does not address finger-to-key (top surface of key) and fingernail-to-key impact sounds.

Several circumstances are illustrative of problems associated with fingernail-to-key impact noise.

Long artificial fingernails may be especially loud in office environments, generating sounds that grate on the listener's nerves. The listener may try wearing headphones, but this is not optional since desired hearing may be impaired such as when people approach the listener's cubicle. The listener may not know how to approach the offending typist or may feel that fans or even a noise machine is needed. Worse, the listener may feel they can't be the only person who the key impact sound irritates.

In some settings such as a public library people can be annoyed by loud typing that is very fast and furious. It may be distracting to the point that the only thing a listener can concentrate on is how much more slowly the listener is typing in comparison.

The present inventor discovered that existing office noise abatement programs focus on dampening noise by using barriers (such as acoustic tiles, acoustic cubicle wall material, and the like), moving noisy equipment such as printers into enclosed printer rooms, adding sources of background or “white” noise, and so forth, and that little focus is given to the finger-to-key or fingernail-to-key impact noise associated with the use of data entry devices such as computer keyboards or data entry keypads. The present inventor discovered that using individual key filters 14 on keyboards and key pads substantially reduces finger-to-key and fingernail-to-key impact noise problems.

The present inventor discovered individual key filters such as that shown in FIG. 1 may be adhered on the top surface 38 of each key so as to provide sound dampening. The individual key filters 14, according to one embodiment, comprise a transparent and resilient material 40 that can be applied to the top of a key (covering the top surface of the key) and subsequently peeled off the top of the key and reapplied as necessary or convenient. Preferably, with the individual key covers in place, the resulting keyboarding noise is substantially reduced in its overall magnitude. In one embodiment, the material covering the top of the individual key effectively filters the finger-to-key and/or fingernail-to-key sounds (by reducing the frequency content of noise created by such finger-to-key and/or fingernail-to-key impacts) and also the impacts themselves (by absorbing the initial downward travel, and hence initial impact, as the finger and or fingernail compresses the resilient cover (filter) material before continued downward travel begins to depress the key and its mechanisms that actuate or trigger the intended data entry).

Further, the present inventor discovered that placement of individual key filters having differing thicknesses or resilience or absorbency from one another such as shown in FIGS. 5-7 may be used so as to further frustrate counter-surveillance or analysis of key strike recordings. For example, individual key filters 14 having a 1 mm thickness may be used on more frequently used keys whereas 0.5 mm thick covers may be used elsewhere. As another example, the material thickness may be randomized or varied from key filter to key filter or randomized from region to region within each individual key filter 14. As yet another example, the material thickness may be engineered so as to correspond with the most common frequency of use. That is, a histogram showing the average frequency of use for each key on a typical keyboard (for a typical sample text) may be used to determine the relative thicknesses and engineered acoustic dampening incorporated into each individual key filter 14.

The present inventor also discovered improvements in wear. By using individual key filter 14 one may be able to increase longevity and, thus, reduce costs for equipment purchases and so forth associated with the use of data entry devices which use keys or the like.

As mentioned, the individual key filters 14 are each preferably sized so as to fit over the top surface 38 of a key 30, covering only the inside (typically) cupped area 34. The shoulders or sides 46 of a typical key 30 need not be, and preferably are not, covered by the individual key filter 14. Any tactile features in this top surface region, such as the typically “J” key 36 tactile (reference ridge) feature 32, may be covered over by the filter 14 material (see FIGS. 3 and 4). Although the top surface 38 is rounded generally, the filter 14 is preferably of a simple, efficient rectangular shape as in FIG. 2 (although different standardized rounded off shapes may be used). FIG. 2 shows a simple filter 14 having a length 22 and width 20, with the corners 24 left uncut.

FIGS. 5-7 illustrate different compositions of the resilient material 40. FIG. 5 is a side view of an exemplary individual key filter 50 having a variable or, preferably, randomized thickness across the filter's length and width. Each of the thicknesses 52, 54, and 56 are different from one another, ideally in a randomized manner, thus absorbing fingernail-to-key impacts in different ways depending upon where across the filter top surface the filter is struck.

FIG. 6 depicts an exemplary filter 60 having areas of different resilience characteristics across the filter's length and width. Even though a constant (uniform) thickness 62 is shown, the differences in resilient material throughout provide different dampening depending upon where the filter is struck. Each of these regions 61a, 61b, 62a, 62b, 63, 67a, and 67b may be of a different diameter resilient material, for example. A fingernail impact at 62a may involve compression (an absorption of impact) in regions 62a and 61b. In 61a, the resilience (compressibility, recovery rate, density, etc.) involves regions 61a and 61b, or 61a and 62b depending upon where along 61a the impact is located. An impact in region 63, however, involves only the material in that particular region 63. An impact in region 67a involves the resilience characteristics in 67a insofar as absorption and noise dampening into the thickness 64 and in region 67b insofar as absorption and noise dampening into the thickness 66. Impacts in border areas, i.e. between regions such as 63 and 67a, may involve resilience characteristics of all the regions involved and interactions between them.

FIG. 7 depicts another filter 70 of non-uniform thickness, but the resilient material is shown broken into regions 71, 73, and 77 each having a particular thickness and, optimally, different resilience, or each may be the same. For example regions 71, 73, and 77 may each have different densities and tend to absorb impacts and dampen noise differently. On the other hand if all regions 71, 73, and 77 are of the same resilient material, then the variation in material thickness (i.e. thickness 76 in regions 71, thickness 74 in regions 73, and thickness 72 in region 77) provide differences in the acoustical dampening depending upon where along the top surface of the filter the filter is struck.

Other patterns and arrangements of resilient material may be used than the examples shown in FIGS. 5, 6, and 7. Combinations of the arrangements shown in FIGS. 5-7 may also be used. The present inventor discussed that the more varied the resilient material (or the more random the resilient material) can be made, the less predictable any undampened or remaining fingernail-to-key or finger-to-key impact noise will be, and thus the more difficult it would be to decipher recorded percussive sounds from a typist using keys equipped with individual key filters 14.

In a notable case involving a medical transcriptionist who had been using the same keyboard for several years, the most frequently used keys had been completely worn through, exposing the mechanism beneath. The keyboard still worked fine, however there were holes worn through the top surfaces on those keys receiving the most frequent and severe impacts. Placement (and possibly successive replacement or over-placement/reapplication) of individual key filters 14, the present inventor discovered, would substantially eliminate such key wear problems.

Preferably, use of individual key filters 14 decrease office tension between those who have manicured fingernails that are loud when keyboarding and those that do not have such fingernails. The use of the disclosed individual key filters 14 to reduce finger-to-key and fingernail-to-key impact noise may also improve the overall productivity within the office, reduce headaches and annoyance caused from the repeating loud key strokes, thus creating improved working environments.

With regard to the material used for the individual key filters 14, preferably a Polyurethane resin is used. Alternatively, the individual key filters may comprise Neoprene, felt, EVO, cork, vinyl's, foam, silicone, or another material with a thickness that can insulate the sound and distribute the percussion on the keys after impact. In one embodiment, the material used may be printed or embossed (for the symbols) with an adhesive that permits the key covers to be taken on and off several times for easy placement and for re-placement of worn or non-sticking keys. In a preferred embodiment, an adhesive downward facing surface is capable of permanently securably fastening the individual key filter 14 to the top surface 38 of the key 30. Preferably, material comprising the individual key filters needs to be of flexible rebounding polymers that have sound dampening qualities.

In one embodiment, the individual key filter 14, is self adhesive (so as to stick to the top surface of a key) die-cut or laser cut material sized so as to fit on the top surface of the key, having a thickness greater than a normal sheet of paper and with a resilience so as to deflect and absorb the impact of a finger or fingernail that strikes downward into the surface of the key (and thereby striking the key filter) and being preferably transparent so that the key notations (i.e. letter or number) remains clearly readable through the individual key filter material. Less preferably, however, the individual key filter may be of a translucent or even an opaque material. In one embodiment the individual key filter is 1 mm thick. In one embodiment the individual key filter is 2 mm thick. In one embodiment, the thickness of the key filter varies from filter to filter, and/or within regions of each filter, and may be engineered so as to maximally dampen and distort (or make less decipherable) impact sound.

In a preferred embodiment, a set of steel rule die cut individual key filter 14 comprises 0.063″ thick pressure sensitive adhesive coated (PSA) urethane, each filter sized approximately the same to fit over the top area 38 of each of the standard (26 alphabet) keys of a standard computer keyboard. Also in a preferred embodiment, the material used for each filter 30 comprises non-bacteria hosting or aliphatic material such that finger contact with the top surface of each filter is less likely to spread bacteria from key to key or from key to other surfaces. Use of an anti-bacterial material on top coating for each filter 14 may also be preferred, especially where the spread or transfer of harmful bacteria is of concern. Such situations may include filters 14 used on keypads or keyboards available for public use as for public library computers and the like.

The terms and expressions which have been employed in the foregoing specification are used therein as terms of description and not of limitation, and there is no intention in the use of such terms and expressions of excluding equivalents of the features shown and described or portions thereof, it being recognized that the scope of the invention is defined and limited only by the claims which follow.

What is claimed is:

1. An individual key filter capable of reducing fingernail-to-key impact noise and reducing percussive sound generated by fingernail-to-key impacts associated with the use of data entry devices such as computer keyboards or other data entry keypad devices, said individual key filter having an adhesive downward facing surface capable of securably fastening said individual key filter to a top surface of a key usable with said keyboards or other keypad devices, an upward facing surface sized to cover said top surface of said key, and resilient material between said downward facing surface and said upward facing surface capable of absorbing fingernail-to-key impacts for reducing noise caused thereby.

2. The individual key filter of claim 1 wherein said upward facing surface is sized to fit a plurality of different keys comprising said keyboards or other keypad devices.

3. The individual key filter of claim 1 wherein said filter is transparent so that said top surface of said key is clearly visible through said filter.

4. The individual key filter of claim 1 wherein said resilient material has non-uniform thickness across said upward facing surface.

5. The individual key filter of claim 1 wherein said resilient material has randomized thickness across said upward facing surface.

6. The key filter of claim 5 wherein said resilient material in each of a plurality of filters has randomized thickness from filter to filter so as to lower a likelihood that any two filters used adjacent to one another are similar.

7. The key filter of claim 1 wherein said resilient material includes non-uniform resilience characteristics across said upward facing surface.

8. The key filter of claim 7 wherein said resilience material in each of a plurality of filters has non-uniform resilience characteristics from filter to filter so as to lower a likelihood that any two filters used adjacent to one another are similar.

9. The key filter of claim 1 wherein said adhesive downward facing surface is capable of permanently securably fastening said individual key filter to said top surface of said key.

10. The key filter of claim 1 wherein said upward facing surface is non-bacteria hosting.
